(19) United States
(12) Patent Application Publication
(10) Pub. No.: US 2026/0123355 A1
(43) Pub. Date: Apr. 30, 2026

(54) BONDING APPARATUS

(71) Applicant: Samsung Electronics Co., Ltd., Suwon-si (KR)

(72) Inventors: Jungyu Lee, Suwon-si (KR); Dongyoon Koo, Suwon-si (KR); Minwoo Rhee, Suwon-si (KR); Sungmin Ahn, Suwon-si (KR); Seungyeol Oh, Suwon-si (KR); Kangsan Lee, Suwon-si (KR)

(21) Appl. No.: 19/177,991

(22) Filed: Apr. 14, 2025

(30) Foreign Application Priority Data
Oct. 31, 2024 (KR) 10-2024-0152972

(51) Int. Cl. H01L 21/683; H01L 21/67; H01L 21/68

(52) U.S. Cl. CPC H10P 72/78; H10P 72/0438; H10P 72/53

(57) ABSTRACT

A bonding apparatus for bonding a second substrate to a first substrate includes a support unit and a bonding unit. The support unit is configured to support the first substrate. The bonding unit is above the support unit and is configured to attach the second substrate. The bonding unit includes a tip member facing the support unit and a head member on the tip member. The tip member includes: a first part having a first region and a second region surrounding the first region, wherein the bonding apparatus is configured to eject a gas from the first region and the bonding apparatus is configured to form a vacuum in the second region; and a second part extending from the first part toward the head member. An area of a transverse section of the first part is less than an area of a transverse section of the second part.

### CROSS-REFERENCE TO RELATED APPLICATION

This application is based on and claims priority under 35 U.S.C. § 119 to Korean Patent Application No. 10-2024-0152972, filed on Oct. 31, 2024, in the Korean Intellectual Property Office, the disclosure of which is incorporated by reference herein in its entirety.

### FIELD

The inventive concept relates to a bonding apparatus, and more particularly, to a bonding apparatus for bonding a semiconductor die to a semiconductor die, a semiconductor die to a wafer, or a wafer to a wafer.

### BACKGROUND

Semiconductor devices having a stack structure of semiconductor chips may be beneficial for increasing the mounting density of semiconductor chips, for reducing the length of electrical connection paths between semiconductor chips, and for high-speed signal processing. To manufacture a semiconductor device having a stack structure of semiconductor chips, a method of stacking semiconductor chips by arranging a film including an adhesive component between the semiconductor chips has been used. However, recently, a direct bonding method to directly bond semiconductor chips to each other without a separate adhesive medium has been used.

### SUMMARY

Aspects of the present disclosure and inventive concepts provide a bonding apparatus capable of performing a high-quality bonding process.

Also, the problems to be solved by the technical ideas of the present inventive concepts are not limited to those mentioned above, and the inventive concepts can be clearly understood by those skilled in the art from the description below.

According to some embodiments, a bonding apparatus for bonding a second substrate to a first substrate includes a support unit and a bonding unit. The support unit is configured to support the first substrate. The bonding unit is above the support unit and is configured to attach the second substrate. The bonding unit includes a tip member facing the support unit and a head member on the tip member. The tip member includes: a first part having a first region and a second region surrounding the first region, wherein the bonding apparatus is configured to eject a gas from the first region and the bonding apparatus is configured to form a vacuum in the second region; and a second part extending from the first part toward the head member. An area of a transverse section of the first part is less than an area of a transverse section of the second part.

According to some embodiments, a bonding apparatus for bonding a second substrate to a first substrate includes a support unit and a bonding unit. The support unit configured to support the first substrate. The bonding unit is above the support unit and is configured to attach the second substrate. The bonding unit includes a tip member facing the support unit and a head member on the tip member. The tip member is attachable to and detachable from the head member. The tip member includes a first region and a second region surrounding the first region, wherein the bonding apparatus is configured to generate a positive pressure toward the first substrate in the first region, and the bonding apparatus is configured to generate a negative pressure toward the head member in the second region. The bonding apparatus is configured to protrude a portion of the second substrate corresponding to the first region toward the first substrate using the positive pressure, and the bonding apparatus is configured to attach another portion of the second substrate corresponding to the second region to the second region using the negative pressure. The bonding apparatus is configured to move the bonding unit toward the support unit such that the protruding portion of the second substrate comes into contact with the first substrate, and the second substrate is bonded to the first substrate.

According to some embodiments, a bonding apparatus for bonding a second substrate to a first substrate includes a support unit, a bonding unit, an alignment unit, and a pressure unit. The support unit is configured to support the first substrate. The bonding unit is above the support unit and is configured to attach the second substrate. The alignment unit is configured to measure a position of the first substrate and a position of the second substrate. The pressure unit is configured to provide a gas and a vacuum to the bonding unit. The bonding unit includes a tip member and a head member. The tip member includes a first part and a second part extending from the first part, the second part having a larger transverse section than the first part, the first part including a first region and a second region surrounding the first region, wherein the bonding apparatus is configured to eject the gas from the first region and to form a positive pressure toward the first substrate, the bonding apparatus is configured to form a negative pressure in the second region by the vacuum, and the first region and the second region face the support unit. The tip member is removably attached to the head member. The bonding apparatus is configured to protrude a portion of the second substrate corresponding to the first region toward the first substrate using the positive pressure, and the bonding apparatus is configured to attach another portion of the second substrate corresponding to the second region to the second region using the negative pressure. The bonding apparatus is configured to move the bonding unit toward the support unit such that the protruding portion of the second substrate comes into contact with the first substrate, and the second substrate is bonded to the first substrate.

### BRIEF DESCRIPTION OF THE DRAWINGS

Embodiments will be more clearly understood from the following detailed description taken in conjunction with the accompanying drawings in which:

FIG. 1 is a schematic diagram of a configuration of a bonding apparatus according to some embodiments;

FIG. 2 is a schematic perspective view of a tip member in FIG. 1;

FIG. 3 is an enlarged perspective view of a region A in FIG. 2;

FIG. 4 is a schematic cross-sectional view of a bonding unit in FIG. 1;

FIGS. 5 and 6 are respectively a schematic perspective view and a schematic plan view of a modification of a tip member;

FIG. 7 is a cross-sectional view illustrating a process of moving a second substrate to a center of a bonding unit;

FIGS. 8A to 8C are diagrams illustrating a process of bonding a first substrate to a second substrate by a bonding apparatus, according to some embodiments; and

FIG. 9 is a flowchart of a bonding method performed by a bonding apparatus, according to some embodiments.

### DETAILED DESCRIPTION OF THE EMBODIMENTS

Hereinafter, embodiments are described in detail with reference to the accompanying drawings. However, the inventive concepts should not be construed as being limited to the embodiments and may be embodied in other various forms. The embodiments are provided to fully convey the scope of the inventive concepts to those skilled in the art rather than to allow the inventive concepts to be fully completed.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

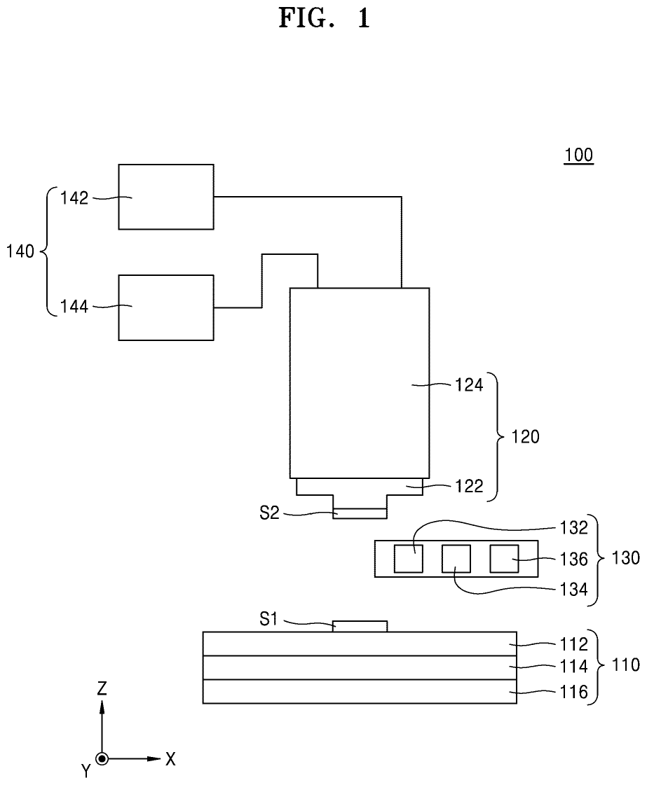

Further, spatially relative terms, such as “under,” “below,” “lower,” “over,” “upper”, etc., may be used herein for ease of description to describe one element or relationship of structures to another element or structure as illustrated in the drawings. FIG. 1 is a schematic diagram of a configuration of a bonding apparatus according to some embodiments.

Referring to FIG. 1, a bonding apparatus 100 may include a support unit 110, a bonding unit 120, an alignment unit 130, and a pressure unit 140. For the purpose of explanation, the bonding apparatus 100 has a primary or longitudinal axis Z, a first transverse axis X perpendicular to the Z-axis, and a second transverse axis Y perpendicular to the Z-axis and the X-axis.

The support unit 110 may support a first substrate S1. The support unit 110 may include a support plate having a flat top surface and may fix the first substrate S1 in a vacuum-adsorption manner.

For example, the support unit 110 may include a vacuum chuck 112 for adsorbing or holding the first substrate S1, a rotation actuator 114 for rotating the first substrate S1, and a support 116 for supporting the rotation actuator 114

The vacuum chuck 112 may stably fix the first substrate S1. A plurality of vacuum holes may be formed in the top surface of the vacuum chuck 112. The vacuum holes may be connected to a vacuum line formed inside the vacuum chuck 112. The vacuum holes may be arranged in a pattern, which may be an optimal pattern, to apply a uniform adsorption or holding force to the entire area of the first substrate S1.

The surface of the vacuum chuck 112 may be precisely machined to have a high degree of flatness. Accordingly, the first substrate S1 may be supported in a completely flat state without deformation. The surface of the vacuum chuck 112 may include a material having a high wear resistance such that the surface quality of the vacuum chuck 112 may be maintained even with repeated use.

The rotation actuator 114 may perform a function of precisely rotating the first substrate S1 (e.g., about a rotation axis parallel to the Z-axis). The rotation actuator 114 may include a high-precision servo motor. The rotation actuator 114 may also precisely control a rotation angle by using an encoder. This precise rotation control may enable an accurate angular alignment between the first substrate S1 and a second substrate S2.

A rotation axis of the rotation actuator 114 may substantially exactly coincide with a center of the vacuum chuck 112. Thus, an eccentricity of the first substrate S1 during rotation may be reduced or minimized and substantially exact center alignment may be enabled. The rotation actuator 114 may have high positional precision by using a precise gear structure without backlash.

The support 116 may stably support the rotation actuator 114 and provide structural stability for the support unit 110. The support 116 may include a high-stiffness material and may include a vibration damping structure capable of effectively blocking external vibration. The vibration damping structure may prevent micro-vibration which may occur during a bonding process from being transmitted to the first substrate S1.

The support 116 may be designed to have a structure that may minimize thermal deformation. Accordingly, the precision of the support unit 110 may be maintained even during long-term operation. The material and structure of the support 116 may have characteristics of a low coefficient of thermal expansion and satisfactory thermal conductivity.

The support unit 110 may further include a tilting mechanism capable of finely adjusting the horizontal level of the first substrate S1. The tilting mechanism may be implemented by a three-point support method, and a piezo actuator may be mounted on each point to enable precise height adjustment. Accordingly, the parallelism between the first substrate S1 and the second substrate S2 may be optimized.

The support unit 110 may also include a temperature control function. A cooling/heating channel having a high thermal conductivity may be formed inside the vacuum chuck 112. The cooling/heating channel may be connected to an external thermostatic circulator and may precisely control the temperature of the first substrate S1. This temperature control may minimize the deformation of a substrate due to heat during a bonding process and may be useful when bonding at a certain temperature is required.

Each component of the support unit 110 may be designed in a modular structure, thereby facilitating maintenance or replacement. In particular, the vacuum chuck 112 may be designed to have a replaceable structure so as to be able to correspond to the first substrate S1 of various sizes.

Through these sophisticated structure and function of the support unit 110, the first substrate S1 may be stably supported and precisely controlled so that substrate bonding of high quality may be possible. In particular, the uniform adsorption or holding force of the vacuum chuck 112, the precise angle control of the rotation actuator 114, and the stable structure of the support 116 may contribute to high precision of the manufacture of advanced semiconductor devices.

For example, the bonding unit 120 may include a tip member 122 facing the support unit 110 (e.g., in a direction parallel to the Z-axis) and a head member 124 arranged or disposed on or engaging the tip member 122.

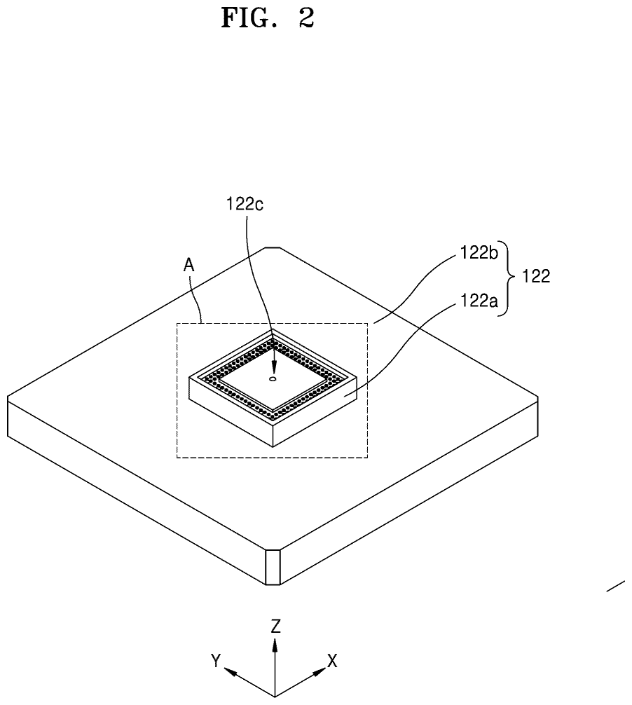

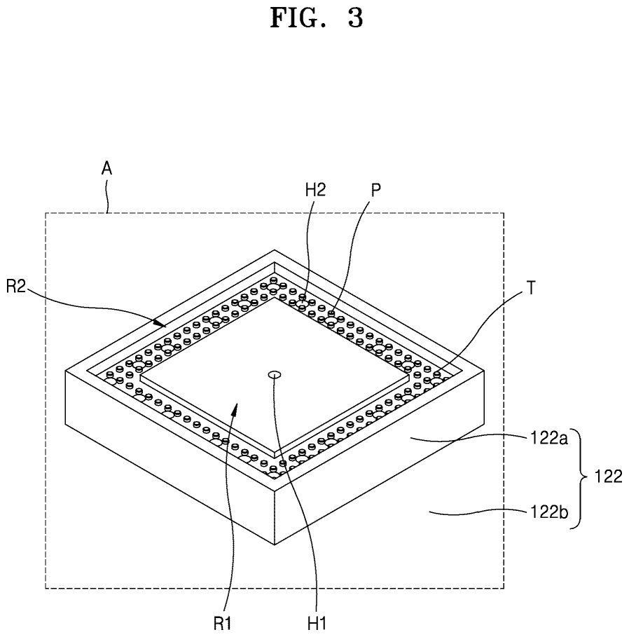

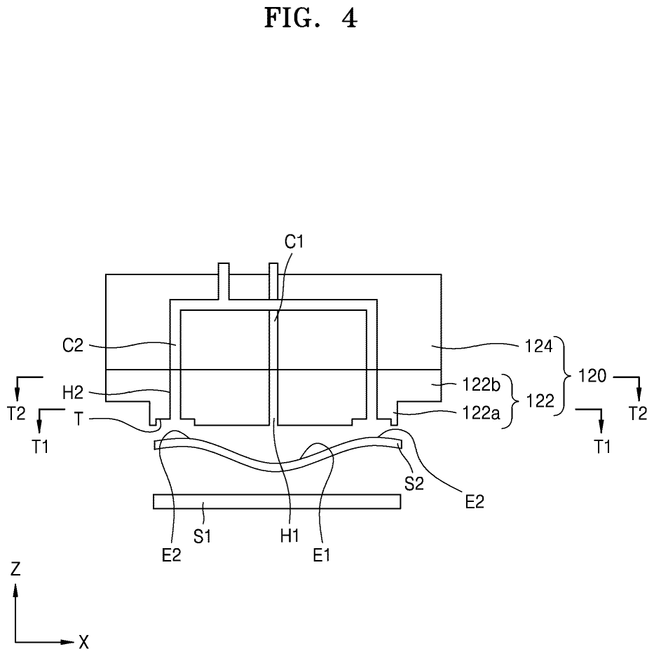

FIG. 2 is a schematic perspective view of the tip member 122 in FIG. 1. FIG. 3 is an enlarged perspective view of a region A in FIG. 2. FIG. 4 is a schematic cross-sectional view illustrating the bonding unit 120 in FIG. 1.

Referring to FIGS. 2 to 4, the tip member 122 may be made of metal or ceramic, which has a high stiffness, a high heat resistance, and a high wear resistance. For example, the tip member 122 may be made of metal, such as stainless steel, an aluminum alloy, or a titanium alloy, or ceramic, such as alumina (Al₂O₃), silicon nitride (Si₃N₄), or silicon carbide (SiC). Through such material selection, the shape and performance of the tip member 122 may be stably maintained even with repeated bonding operations.

For example, the tip member 122 may have a dual structure consisting of a first part 122a and a second part 122b. The area of a transverse section T1-T1 (FIG. 4) of the first part 122a of the tip member 122 may be smaller than the area of a transverse section T2-T2 (FIG. 4) of the second part 122b of the tip member 122. The “area of the transverse section” refers to the cross-sectional area of the corresponding first part 122a or second part 122b in a plane parallel to a transverse plane defined by the X-axis and the Y-axis (i.e., a plane orthogonal to the Z-axis). The transverse widths of the first part 122a along the X-axis and along the Y-axis may be smaller than the transverse widths of the second part 122b along the X-axis and along the Y-axis, respectively. For example, as shown in FIGS. 1 and 2, the first part 122a and the second part 122b of the tip member 122 may have a double-step structure. For example, the longitudinal section of the first part 122a of the tip member 122 may have an inverted trapezoidal shape in a direction toward the head member 124 (i.e., a direction parallel to the Z-axis).

The second substrate S2 may be attached, secured or held to a surface 122c of the first part 122a of the tip member 122, which faces the support unit 110. The area of a surface 122c of the first part 122a of the tip member 122 may be substantially the same as the area of the side or surface of the second substrate S2 that faces the tip member 122 when the second substrate S2 is held to the tip member 122.

The tip member 122 having a dual structure consisting of the first part 122a and the second part 122b may bond the second substrate S2 to the first substrate S1 without interference with other chips already bonded to the first substrate S1.

In detail, the first part 122a of the tip member 122 may protrude further than the second part 122b of the tip member 122 along the Z-axis and toward the support unit 110 and thus directly contact the second substrate S2. Due to this structure, the tip member 122 may selectively approach only a certain region of the surface of the first substrate S1 and thus accurately position the second substrate S2 even in a narrow space between chips already bonded to the first substrate S1.

The second part 122b of the tip member 122 may be higher than the first part 122a of the tip member 122 and thus avoid physical contact with the already bonded chips. Accordingly, the already bonded chips may be prevented from being damaged or displaced.

The small contact area of the surface 122c of the first part 122a of the tip member 122 may enable precise bonding, which is particularly important to a high-density integrated circuit. In addition, bonding may be gradually started from the center, minimizing air traps and promoting uniform bonding. As a result, high-quality bonding may be possible.

Flexibility capable of responding to existing chips having various thicknesses may be provided by adjusting the height difference between the first part 122a and the second part 122b of the tip member 122.

Because the transverse area of the second part 122b of the tip member 122 is larger than the transverse area of the first part 122a of the tip member 122, heat generated during a bonding process may be effectively dispersed. Due to these characteristics, the tip member 122 having a dual structure may be particularly useful for manufacturing a complex three-dimensional (3D) integrated circuit or multi-chip module.

Consequently, when the second substrate S2 is additionally bonded to the first substrate S1 to which multiple layers of chips have already been bonded, the dual structure of the tip member 122 may accurately and stably bond the second substrate S2 to the first substrate S1 while protecting the existing structures on the first substrate S1. Accordingly, productivity and reliability may be greatly increased in a process of manufacturing a high-performance semiconductor device, and complex and sophisticated integrated circuit design may be possible.

Although the tip member 122 of FIGS. 2 and 3 has a dual-step structure, the inventive concepts are not limited thereto. A tip member may have a multi-step structure having at least three steps. This multi-step structure may enable more sophisticated bonding control and may be effectively used particularly when chips of various heights exist on the first substrate S1.

For example, the tip member 122 having three steps may include a first part, a second part, and a third part. The first part may be the most protruding part of the tip member 122 and may directly contact the second substrate S2, the second part may be at a higher position than the first part, and the third part may be at a higher position than the second part.

As shown in FIGS. 2 and 3, the first part may include a first region R1, in which a positive pressure hole H1 is formed, and a second region R2, in which a negative pressure hole H2 is formed. The second part and the third part may prevent interference with existing chips of different heights.

This triple-step structure may be optimized according to the heights of existing chips. For example, when chips, such as a memory chip and a logic chip, which have different height from each other, have already been bonded to the first substrate S1, the height of each step may be designed according to the heights of the chips.

Furthermore, a tip member may have a structure having four or more steps. This multi-step structure may be particularly useful for complex 3D integrated circuits. The steps may effectively prevent interference with existing chips having different heights from each other, and accordingly, more complex stack structures may be realized.

The tip member 122 having a multi-step structure may have a slope on a side of each step. This side slope may more effectively prevent interference with existing chips and may increase structural stability.

The first region R1, in which a positive pressure is generated by ejecting gas, and the second region R2, which surrounds the first region R1 and in which a negative pressure is generated by sucking in gas, may be formed in the first part 122a of the tip member 122. At least one positive pressure hole H1 may be arranged, defined or located in the first region R1, and a trench T may be arranged, defined or located in the second region R2. A plurality of negative pressure holes H2 may be arranged, defined or located in the trench T. The positive pressure hole H1 and the negative pressure holes H2 may be formed in a direction from the bonding unit 120 toward the support unit 110 (e.g., parallel to the Z-axis).

A plurality of protrusions P may be arranged among the negative pressure holes H2 in the trench T. The height of each of the protrusions P may be substantially the same as the depth of the trench T. The top end of each protrusion P may be coplanar with the first region R1.

A portion E1 of the second substrate S2 may be forcibly deformed to protrude toward the first substrate S1 by the gas ejected from or through the positive pressure hole H1. The negative pressure holes H2 may enable the second substrate S2 to be stably supported and effectively vacuum-adsorbed or vacuum-held. Vacuum generated through the negative pressure holes H2 may allow an outer portion E2 of the second substrate S2 to closely contact the tip member 122.

According to some embodiments, the bonding apparatus 100 may press the top surface of the second substrate S2 through or using gas ejected from the positive pressure hole H1 rather than directly pressing the second substrate S2 through an object such as a pressing pin. The gas may apply a downward force not only to the center of the second substrate S2 vertically below the positive pressure hole H1 but also to a portion around the center of the second substrate S2.

In other words, the gas ejected from the positive pressure hole H1 through dispersion of a naturally occurring gas flow may be dispersed, deforming the second substrate S2, and may fill the space formed by deformed second substrate S2 with a uniform pressure, thereby applying a force to the second substrate S2. The space may be larger or smaller than the first region R1 and may be formed across at least a portion of the second region R2. Because a uniform force may be applied to the second substrate S2 through the flat tip member 122 after the second substrate S2 is bonded to the first substrate S1, high-quality bonding may be possible. Through this bonding, misalignment of die-to-die bonding, die-to-wafer bonding, or wafer-to-wafer bonding may be reduced. Accordingly, the bonding apparatus 100 may increase the productivity and yield of die-to-die bonding, die-to-wafer bonding, or wafer-to-wafer bonding.

The tip member 122 of FIGS. 2 and 3 may include one positive pressure hole H1 at the center of the first region R1. However, in an example modification, a plurality of positive pressure holes H1 may be arranged in a central portion of the first region R1 of the tip member 122. In this configuration, the central portion of the second substrate S2 may be more uniformly deformed.

The positive pressure holes H1 may be symmetrically arranged with respect to the center of the first region R1. For example, the positive pressure holes H1 may be arranged at the center point of the first region R1 and in a circular pattern around the center point of the first region R1 or may be arranged in a lattice pattern. The symmetric arrangement of the positive pressure holes H1 may allow uniform pressure to be applied to the second substrate S2, so that the second substrate S2 may be evenly deformed without being biased to one side.

Each of the positive pressure holes H1 may have a different size according to the location thereof. For example, a positive pressure hole H1 at the center of the first region R1 may have a relatively large diameter, and the diameter of the positive pressure hole H1 may decrease toward the edge of the first region R1. The change in the size of the positive pressure holes H1 may allow the second substrate S2 to naturally curve from the center of the second substrate S2 to the edge thereof.

Positive pressure holes H1 on the same radius may have the same size, which may help secure radial symmetry of the second substrate S2. The change in the size of the positive pressure holes H1 may be optimized according to the characteristic, such as the size or the thickness, of the second substrate S2.

The pressure of gas supplied through each of the positive pressure holes H1 may be individually controlled together with the size of each positive pressure hole H1. A gas of relatively low pressure may be supplied to a large positive pressure hole H1 at the central portion of the first region R1, and a gas of relatively high pressure may be supplied to a small positive pressure hole H1 at the outer portion of the first region R1. This combination of pressure and hole size may enable more sophisticated deformation control of the second substrate S2.

The distribution of sizes of the positive pressure holes H1 may be designed considering the distribution of stiffness of the second substrate S2. For example, when the central portion E1 of the second substrate S2 has a higher stiffness than the outer portion E2 thereof, the size of a positive pressure hole H1 in the central portion may be increased to provide a sufficient deformation force.

Compared to the configuration of a single positive pressure hole H1, this configuration of multiple positive pressure holes H1 may enable more sophisticated shape control of the second substrate S2. Particularly, the configuration of multiple positive pressure holes H1 may be useful for a large substrate or a process in which uniform bonding is important. Even when a substrate has warpage or distortion, the configuration of multiple positive pressure holes H1 may enable stable bonding by compensating for the warpage or distortion.

The multiple positive pressure holes H1 may also provide cooling effect for the second substrate S2 by supplying gas in a distributed manner. This may help minimize thermal deformation that may occur during a bonding process.

The configuration of multiple positive pressure holes H1 may also have an advantage in terms of reliability by continuously performing functions through some holes even if other holes are blocked. This redundancy may reduce the need for maintenance during long-term use.

An example modification using multiple positive pressure holes H1 may enable more precise control of the second substrate S2, thereby increasing the reliability and quality of a bonding process.

The tip member 122 may be attached to and detached from the head member 124. This may greatly increase the flexibility and economic feasibility of equipment by allowing only tip member 122 to be replaced instead of replacing an entire bonding unit whenever the size or shape of a substrate is changed.

For example, the tip member 122 may be attached to or detached from the head member 124 by using a vacuum-adsorption or vacuum-holding method. In detail, the tip member 122 may be attached to the head member 124 by a negative pressure generated by the head member 124. For this operation, a plurality of vacuum adsorption holes may be formed in a contact surface 124A of the head member 124, which contacts the tip member 122.

The attachment of the tip member 122 may be accomplished by a negative pressure. In other words, after the tip member 122 is placed at a certain position on the head member 124, a vacuum may be applied through the pressure unit 140, resulting in a negative pressure. The negative pressure may act on the tip member 122 through the vacuum adsorption or vacuum-holding holes, so that the tip member 122 may be firmly attached to the head member 124.

Contrarily, the tip member 122 may be detached from the head member 124 by releasing the negative pressure. When the pressure unit 140 stops supplying the vacuum and provides atmospheric pressure, an adsorption or holding force acting on the tip member 122 may disappear, so that the tip member 122 may be easily detached from the head member 124.

The head member 124 may be arranged on the tip member 122 to support the tip member 122 and may connect the tip member 122 to the pressure unit 140. The head member 124 may include a first channel C1 and a second channel C2 therein.

The first channel C1 may be connected to a gas supply source 142 of the pressure unit 140 and may supply a gas to the positive pressure hole H1 of the tip member 122. The second channel C2 may be connected to a vacuum pump 144 and may provide a vacuum to the negative pressure holes H2.

In detail, the first channel C1 may be formed in a central portion of the head member 124 and connected to the gas supply source 142 of the pressure unit 140. A positive pressure supplied through the first channel C1 may be transmitted to the positive pressure hole H1 of the tip member 122, thereby allowing the central portion of the second substrate S2 to protrude.

The second channel C2 may be formed in an outer portion of the head member 124 and connected to the vacuum pump 144. A negative pressure supplied through the second channel C2 may be transmitted to the negative pressure holes H2, thereby allowing the outer portion of the second substrate S2 to closely contact the tip member 122.

The head member 124 may be manufactured using metal or ceramic, which has a low thermal expansion coefficient and a high stiffness. This may help minimize thermal deformation that may occur during a bonding process and may enable precise pressure control.

As described above, the head member 124 may include a coupling structure for coupling with the tip member 122. In other words, the tip member 122 may be attached to and detached from the head member 124.

For example, the tip member 122 may be attached or held to and detached from the head member 124 through a vacuum adsorption or vacuum holding method. The tip member 122 may be attached to and detached from the head member 124 through a plurality of vacuum adsorption holes or vacuum holding holes (not shown) formed in a contact surface of the head member 124, which contacts the tip member 122. The attachable/detachable mechanism may provide flexibility to accommodate substrates having various sizes and shapes, minimize equipment downtime, and facilitate maintenance. The head member 124 may include three channels connected to vacuum adsorption or holding holes of the tip member 122.

The alignment unit 130 may align the first substrate S1 with the second substrate S2 before the second substrate S2 is bonded to the first substrate S1. For example, the alignment unit 130 may include a photographing member 132, an alignment determiner 134, and an alignment controller 136.

The photographing member 132 may capture the alignment mark of the first substrate S1 and the alignment mark of the second substrate S2 in high resolution. The photographing member 132 may include a high-magnification, high-resolution charge-coupled device (CCD) or complementary metal-oxide-semiconductor (CMOS) camera and may be mounted on a precision stage capable of fine movement in the X, Y, and Z axes. Through this, an optical focal length and field-of-view may be secured.

The photographing member 132 may include a lighting system of various wavelengths. Light sources of various wavelengths, such as white light, ultraviolet light, and infrared light, may be selectively used, and accordingly, an optimal image may be obtained according to the characteristics of the material or alignment mark of a substrate. In particular, when a telecentric lens system is used, the change in a magnification according to the distance to an object may be reduced or minimized, and an accurate image without distortion may be obtained.

The alignment determiner 134 may analyze the image, which is obtained by the photographing member 132, in real time and may determine the alignment state of the first substrate S1 and the second substrate S2. The alignment determiner 134 may include a high-performance image processor and dedicated software and may utilize advanced image processing algorithms, such as a pattern matching algorithm, an edge detection algorithm, and a center extraction algorithm.

The alignment determiner 134 may detect precise positions at a sub pixel level. The alignment determiner 134 may also use a global mapping algorithm considering even non-linear deformation caused by thermal expansion or contraction of a substrate. This may enable precise alignment across the entire substrate.

The alignment determiner 134 may recognize alignment marks having various shapes and have a flexible pattern recognition capability. Positions of alignment marks having various shapes, such as a cross shape, a quadrangular shape, and a circular shape, may be detected with the same level of precision. When necessary, a recognition capability may be further increased by using a pattern recognition algorithm based on deep learning.

The alignment controller 136 may accurately align the first substrate S1 with the second substrate S2 by controlling the movements of the bonding unit 120 and the support unit 110 based on the analysis result of the alignment determiner 134. The alignment controller 136 may include a high-performance real-time control system and may perform precise position control using an advanced control technique such as a proportional-integral-derivative (PID) control algorithm.

The alignment controller 136 may use a hybrid control method that combines feedforward control and feedback control. This may simultaneously ensure high response speed and high precision. In addition, reliable alignment may be realized by generating a motion profile considering inertia or vibration of a substrate.

The alignment unit 130 may include an automatic calibration function. Periodically or when necessary, the alignment unit 130 may automatically verify and correct the accuracy of a system by using a standard calibration pattern. Accordingly, the alignment unit 130 may maintain high precision even when the alignment unit 130 is used for a long time.

The alignment unit 130 may also have a real-time monitoring and logging function. All data in an alignment process may be recorded and analyzed and thus be used as important data for process optimization and quality management. This data may also be used for statistical process control and may help with preventive maintenance of equipment.

The alignment unit 130 may also include a correction function for environmental changes. It may be possible to detect and correct fine deformation of a substrate caused by a change in temperature or humidity in real time, and accordingly, stable alignment performance may be maintained.

The operating principle of the alignment unit 130 is described below. The photographing member 132 may simultaneously capture the alignment mark of the first substrate S1 and the alignment mark of the second substrate S2. At this time, a plurality of photographing members 132 may be simultaneously used according to the size of a substrate.

Subsequently, the alignment determiner 134 may analyze the captured image and calculate an XY-axis error, a rotation error, and a scale error between the first substrate S1 and the second substrate S2.

Subsequently, the alignment controller 136 may generate a correction command based on the calculated errors.

Subsequently, the position of the bonding unit 120 and the position of the support unit 110 may be adjusted according to the correction command. In detail, the XY-axis error may be corrected by the XY stage of the bonding unit 120, the rotation error may be corrected by the rotation actuator 114 of the support unit 110, and the scale error may be corrected by the temperature control system of the bonding unit 120.

After the position adjustment, the alignment marks of the first substrate S1 and the second substrate S2 may newly captured and analyzed, and errors may be newly checked. When necessary, the processes described above may be repeated to carry out fine adjustment until target precision is reached.

The alignment unit 130 may enable high-precision alignment of substrates having micropatterns through the organic combination of the photographing member 132 having high performance, the alignment determiner 134 equipped with a sophisticated image analysis algorithm, and the alignment controller 136 having a precise control capability.

For example, the pressure unit 140 may include the gas supply source 142 supplying gas through the first channel C1 and the vacuum pump 144 providing a vacuum through the second channel C2.

The gas supply source 142 may stably supply high-purity compressed gas and may mainly compress air in the atmosphere and use the compressed air. When necessary, the gas supply source 142 may use an inert gas, such as a nitrogen gas (N₂), an argon (Ar) gas, or a helium (He) gas.

The gas supply source 142 may include a high-pressure gas tank, a pressure regulator, a flow control valve, a filter system, and a pressure sensor. In particular, a mass flow controller (MFC) may be used for flow control, so that a flow rate may be precisely controlled in units of 0.1 sccm and a pressure may be controlled at a high resolution of 0.1 kPa.

The vacuum pump 144 may provide a stable and deep vacuum through the second channel C2. For example, the vacuum pump 144 may include a rotary vane pump forming an initial vacuum and a turbo molecular pump generating a high vacuum and may achieve a deep vacuum of up to 10⁻⁶ Pa.

A vacuum gauge system combining a Pirani vacuum gauge and an ionization gauge may be used to measure a vacuum level in real time, and the vacuum level may be controlled with a high resolution of 0.1 Pa.

For example, the control system of the pressure unit 140 may have a real-time feedback control function, a programmable pressure profile, a safety interlock system, and data logging and analysis functions.

This may provide a substantially optimal pressure environment for each stage of a bonding process and may enable immediate response to abnormal situations that may occur during the process. In addition, a pressure fluctuation caused by a temperature change during the process may be automatically corrected through a temperature correction function, so that a stable pressure environment may be maintained even during a long-term process.

The operating principle of the pressure unit 140 is described below. A vacuum may be formed in the second channel C2 through the vacuum pump 144 such that the second substrate S2 may be adsorbed, pulled, drawn, sucked or held onto the tip member 122. Subsequently, a positive pressure may be applied to the first channel C1 through the gas supply source 142 such that the central portion of the second substrate S2 may protrude. In a bonding process, a substantially optimal bonding condition may be maintained by precisely control the positive pressure and the vacuum. After bonding is complete, residual stress may be minimized by gradually releasing the pressure.

The precise pressure control capability of the pressure unit 140 may play a key role in a bonding process for highly integrated semiconductor chips, in which a minute pressure difference is important. In particular, because sequential bonding from the center to the edge of a semiconductor substrate is possible, the generation of voids may be minimized and uniform adhesion may be secured. As a result, process yield and product quality may be greatly increased.

Although it is illustrated in FIG. 1 that the pressure unit 140 includes one gas supply source 142 and one vacuum pump 144, the inventive concepts are not limited thereto. The pressure unit 140 may include a plurality of gas supply sources 142 and a plurality of vacuum pumps 144. When there are multiple positive pressure holes H1 and multiple negative pressure holes H2, multiple gas supply sources 142 and multiple vacuum pumps 144 may also be provided in correspondence to the multiple positive pressure holes H1 and negative pressure holes H2.

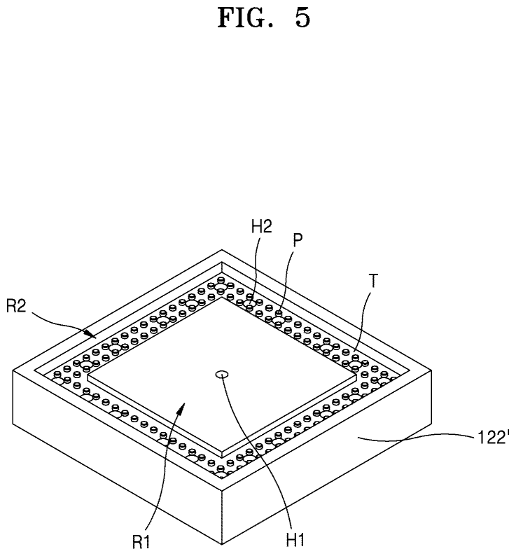

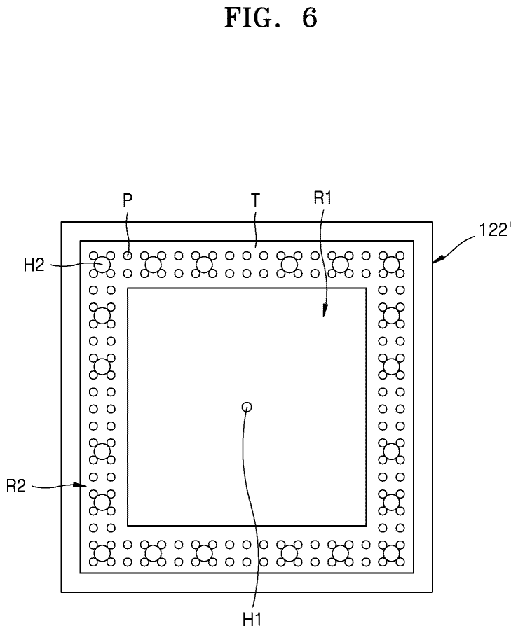

FIGS. 5 and 6 are respectively a schematic perspective view and a schematic plan view of a modification of a tip member.

Referring to FIGS. 5 and 6, unlike the tip member 122 having a dual-step structure in FIGS. 1 and 2, a tip member 122′ may have a single-plane structure.

The tip member 122′ may be effectively used when there are no chips on the second substrate S2 or when the first substrate S1 is bonded to a position sufficiently apart from a chip already bonded to the second substrate S2.

The tip member 122′ may include a single flat surface as a whole and a positive pressure hole H1 and a negative pressure hole H2 in the single flat surface. The positive pressure hole H1 may be arranged in a first region R1 corresponding to a central portion of the tip member 122′, and the negative pressure hole H2 may be arranged in a second region R2 corresponding to an outer portion surrounding the first region R1.

The tip member 122′ having a single-plane structure may uniformly support the entire area of the second substrate S2, thereby minimizing the deformation of the second substrate S2 during a bonding process. Because the second substrate S2 is maintained flat overall, stress after bonding may be uniformly distributed, thereby increasing long-term reliability.

The single-plane structure of the tip member 122′ may be particularly useful when there are not chips on the second substrate S2. In this case, the tip member 122′ may uniformly press the entire area of the second substrate S2, thereby enabling more stable bonding.

The tip member 122′ may also be effectively used when the first substrate S1 is bonded to a position sufficiently apart from a chip already bonded to the second substrate S2. In this situation, a pressure may be uniformly applied across a large area without interference with an existing chip, and accordingly, bonding quality may be increased.

The simple structure of the tip member 122′ may be easily manufactured and cost-effective. In addition, the ease of cleaning and maintenance of the tip member 122′ may also contribute to an increase of an operating time and reduction of maintenance cost on production sites.

The tip member 122′ having a single-plane structure of FIGS. 5 and 6 may be effectively used when there are no chips on the second substrate S2 or when bonding is performed on a position sufficiently apart from an existing chip on the second substrate S2. This structure may provide uniform pressure distribution and the ease of manufacture and maintenance due to simplicity, thereby performing optimally in certain bonding situations.

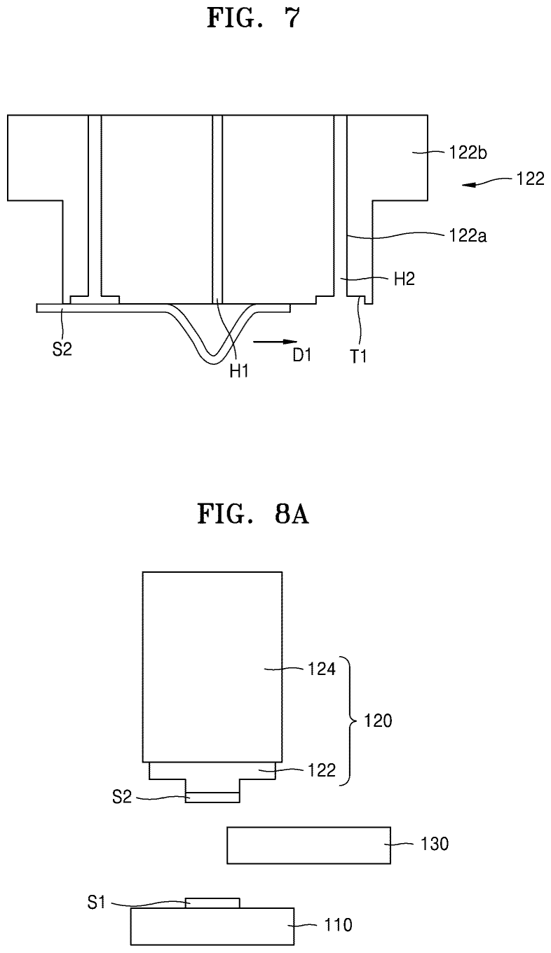

FIG. 7 is a cross-sectional view illustrating a process of moving the second substrate S2 to the center of a bonding unit.

According to some embodiments, when the second substrate S2 is attached to the tip member 122 in a misaligned state, a bonding apparatus may automatically move the second substrate S2 to a central position thereof. A method of automatically centering the second substrate S2 is described below with reference to FIGS. 2, 3, and 7.

A plurality of positive pressure holes H1 ejecting gas and a plurality of negative pressure holes H2 sucking in gas may be formed in a surface of the tip member 122. The positive pressure holes H1 may be concentrated in a central portion of the tip member 122. The negative pressure holes H2 may be arranged in an outer portion, and particularly, near a corner or a vertex of the tip member 122.

The sizes and arrangements of the positive pressure holes H1 and the negative pressure holes H2 may be optimized for the effective control of the second substrate S2. The positive pressure holes H1 may have a relatively small diameter for precise gas ejection. The negative pressure holes H2 may have a larger diameter than the positive pressure holes H1 to provide a sufficient adsorption force.

When the second substrate S2 is attached to the tip member 122 with a deviation from the center of the tip member 122, the negative pressure holes H2 may be exposed without being covered by the second substrate S2. Gas around exposed negative pressure holes H2 may be strongly sucked into the negative pressure holes H2, and accordingly, a gas flow in the vicinity may be accelerated, and a pressure may become lower than the surrounding. An adsorption or holding force through the negative pressure holes H2 may be set within an appropriate range in which the second substrate S2 may be stably controlled.

When such a localized low-pressure region is formed, the second substrate S2 may naturally move in a direction toward the low-pressure region, i.e., in a direction D1 in which the second substrate S2 covers the exposed negative pressure holes H2. Simultaneously, gas may be continuously ejected from the positive pressure holes H1 with a regulated pressure such that the second substrate S2 may be maintained lifted to a certain distance from the tip member 122. The certain distance may be controlled within a substantially optimal range, in which the second substrate S2 may freely move while maintaining stability.

When the second substrate S2 is placed at the center of the tip member 122, all negative pressure holes H2 may be uniformly covered by the second substrate S2. In this state, gas ejected from the positive pressure holes H1 may be uniformly sucked into the negative pressure holes H2 such that surrounding gas at the side edge of the second substrate S2 may be uniformly sucked into the negative pressure holes H2. Due to this balanced gas flow, the second substrate S2 may be stably held at the central position of the tip member 122.

In particular, the sum of cross-sectional areas of the negative pressure holes H2 may be designed to be greater than the sum of cross-sectional areas of the positive pressure holes H1. Accordingly, suction pressure may be always dominant. Even when the second substrate S2 tends to deviate from the central position of the tip member 122, a restoring force may immediately act to return the second substrate S2 to the central position.

Accordingly, this automatic centering mechanism may automatically correct misalignment in a rotation direction. When the second substrate S2 is misaligned with the rotation direction, the second substrate S2 may be rotated by an unbalanced suction force caused by exposed negative pressure holes H2 and thus be aligned with the rotation direction. In this case, the gas ejected from the positive pressure holes H1 may serve as a kind of air bearing between the second substrate S2 and the tip member 122 such that the second substrate S2 may smoothly rotate without friction.

The automatic centering mechanism may move the second substrate S2 to an exact position without physical contact, thereby preventing the surface of the second substrate S2 from being contaminated or damaged. In addition, because gas is continuously ejected from the positive pressure holes H1, the inflow of external particles may also be effectively blocked.

According to some embodiments, unlike a mechanical alignment method according to the related art, the side surface or edge of the second substrate S2 may have no physical contact, and accordingly, generation of particles that may occur in an end portion of the second substrate S2 may be fundamentally prevented. Especially, this may be a very important advantage in semiconductor manufacturing processes requiring high cleanliness.

As described above, according to some embodiments, the position of the second substrate S2 may be precisely controlled through the automatic centering mechanism so that the accuracy and reliability of a subsequent bonding process may be significantly increased. In particular, even the second substrate S2 having an activated surface may be handled safely in a non-contact manner, and accordingly, the inventive concepts may also be effectively applied to highly difficult processes such as direct bonding.

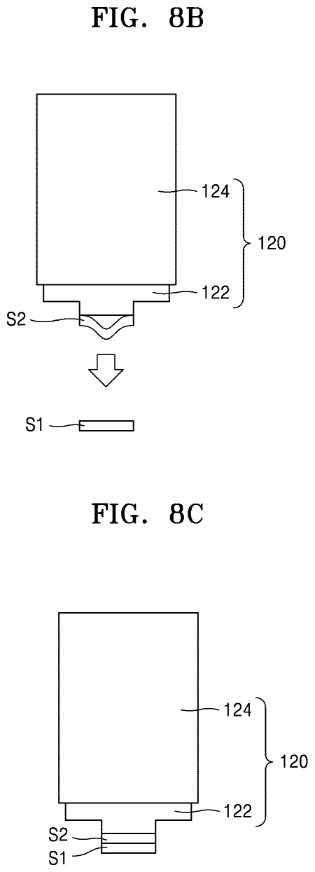

FIGS. 8A to 8C are diagrams illustrating a process, by a bonding apparatus, of bonding the first substrate S1 to the second substrate S2, according to some embodiments.

Referring to FIG. 8A, the second substrate S2 may be attached to the tip member 122 of the bonding unit 120, and the first substrate S1 may be placed on the support unit 110. In this stage, the alignment unit 130 may be placed between the first substrate S1 and the second substrate S2 and may precisely align the first substrate S1 with the second substrate S2. The alignment unit 130 may capture and analyze the alignment mark of the first substrate S1 and the alignment mark of the second substrate S2 and may accurately adjust the relative positions of the first substrate S1 and the second substrate S2. Through this process, the first substrate S1 and the second substrate S2 may be prepared to be bonded to each other in a substantially exactly aligned state.

FIG. 8B illustrates a bonding preparation stage after the alignment is complete. In this stage, gas may be ejected through a positive pressure hole H1 at a central portion of the tip member 122, thereby deforming the central portion of the second substrate S2.

This deformation may cause the central portion E1 of the second substrate S2 to bulge toward the first substrate S1. Simultaneously, the edge portion E2 of the second substrate S2 may be fixed to the tip member 122 by applying a vacuum through negative pressure holes H2 arranged in an outer portion of the tip member 122. This process may prevent voids from occurring during bonding and may enable gradual bonding of the second substrate S2 from the center to the edge thereof.

FIG. 8C illustrates a final bonding stage. The bonding unit 120 may descend toward the support unit 110 such that the deformed second substrate S2 comes into contact with the first substrate S1. At this time, the central portion E1 of the second substrate S2 may first come into contact with the first substrate S1, and bonding may gradually progress to the edge of the second substrate S2. As the bonding progresses, the gas ejection of the tip member 122 through the positive pressure hole H1 may gradually decrease, and the vacuum suction through the negative pressure holes H2 may also be gradually released. Through this process, the first substrate S1 and the second substrate S2 may be gradually bonded to each other from the center to the edge thereof, so that uniform and stable bonding may be carried out without voids or stress concentration.

Through this bonding process, a bonding apparatus of the inventive concepts may accomplish high-quality substrate bonding by realizing precise alignment, prevention of voids, uniform pressure distribution, and the like.

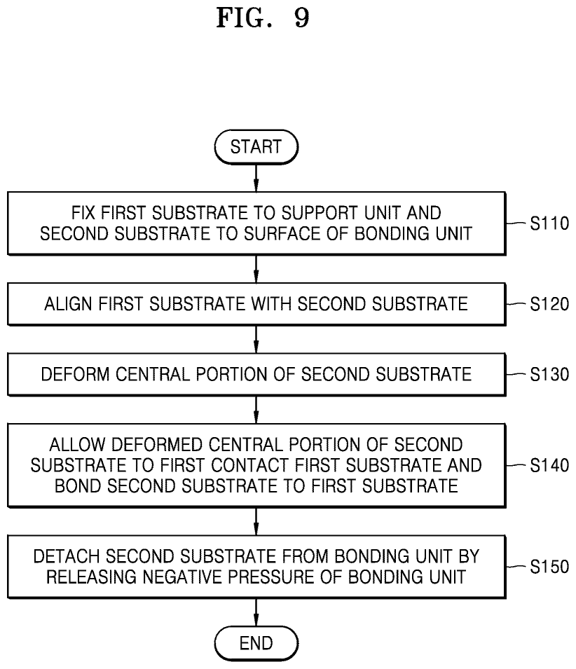

FIG. 9 is a flowchart of a bonding method performed by a bonding apparatus, according to some embodiments.

The bonding method of FIG. 9 may include placing the first substrate S1 on the support unit 110 and attaching the second substrate S2 to the bonding unit 120 in operation S110, aligning the first substrate S1 with the second substrate S2 in operation S120, deforming a central portion of the second substrate S2 in operation S130, allowing the deformed central portion E1 of the second substrate S2 to first come into contact with the first substrate S1 and bonding the second substrate S2 to the first substrate S1 in operation S140, and detaching the second substrate S2 from the bonding unit 120 by releasing a negative pressure of the bonding unit 120 in operation S150.

The first substrate S1 may be placed on the support unit 110 and the second substrate S2 may be attached to the bonding unit 120, in operation S110. The support unit 110 may include the vacuum chuck 112 and stably fix the first substrate S1 through the vacuum chuck 112. The support unit 110 may also include the rotation actuator 114 and may finely adjust the rotation angle of the first substrate S1 in a subsequent alignment process.

The tip member 122 of the bonding unit 120 may have a dual structure of the first part 122a and the second part 122b. The first part 122a may protrude further than the second part 122b and thus directly contact the second substrate S2. The tip member 122 may include a plurality of positive pressure holes H1 and a plurality of negative pressure holes H2 and thus stably fix and control the second substrate S2 in a subsequent process. The positive pressure holes H1 may be concentrated in a central region of the tip member 122, and the negative pressure holes H2 may be mainly arranged in an outer region of the tip member 122.

Subsequently, the first substrate S1 may be aligned with the second substrate S2 in operation S120. The alignment unit 130 may include the photographing member 132, the alignment determiner 134, and the alignment controller 136. The photographing member 132 may capture the alignment mark of each of the first substrate S1 and the second substrate S2 by using a high-resolution CCD camera. The alignment determiner 134 may analyze the captured image in real time and calculate a relative position error between the first substrate S1 and the second substrate S2. The alignment controller 136 may precisely adjusting the position of the rotation actuator 114 of the support unit 110 and the position of the bonding unit 120, based on the analysis result, thereby aligning the first substrate S1 with the second substrate S2 at the submicron level.

After the alignment is complete, the central portion of the second substrate S2 may be deformed in operation S130. In operation S130, the pressure unit 140 may supply gas to the positive pressure holes H1 with a precisely regulated pressure through the first channel C1. Accordingly, the central portion E1 of the second substrate S2 may be deformed into a bulge. Simultaneously, the outer portion E2 of the second substrate S2 may be firmly fixed to the tip member 122 by applying a vacuum to the negative pressure holes H2 through the second channel C2. This substrate deforming mechanism may effectively prevent voids from occurring in a subsequent bonding process.

Subsequently, the deformed central portion E1 of the second substrate S2 may be allowed to first come into contact with the first substrate S1 and the second substrate S2 may be bonded to the first substrate S1, in operation S140. The bonding unit 120 may descend toward the support unit 110 at a precisely controlled speed and pressure. At this time, the bulged central portion E1 of the second substrate S2 may first come into contact with the first substrate S1, and a bonding region may be gradually expanded to the edge of the second substrate S2. As the bonding progresses, the pressure unit 140 may precisely control and reduce a gas ejection pressure through the positive pressure holes H1. This gradual bonding method may prevent voids from occurring and enable uniform bonding.

The second substrate S2 may be detached from the bonding unit 120 by releasing the negative pressure of the bonding unit 120 in operation S150. In operation S150, a vacuum suction force through the negative pressure holes H2 may be released in stages. At this time, the pressure unit 140 may allow the second substrate S2 to be naturally separated from the tip member 122 by gradually stopping the vacuum supply through the second channel C2. This controlled detachment process may prevent unnecessary stress from being applied to a bonded substrate.

This bonding method may realize high-quality substrate bonding through precise alignment, controlled substrate deformation, and gradual bonding. In particular, when the tip member 122 having a dual structure is used, additional bonding may be carried out without interference with other chips already bonded to the first substrate S1. Accordingly, the bonding method may be very effective in manufacturing 3D integrated circuits or complex multi-chip modules. In addition, the bonding method may prevent voids from occurring and realize uniform pressure distribution and minimized thermal stress, thereby providing a core technological advantage in manufacturing high-performance semiconductor devices.

While the inventive concepts have been particularly shown and described with reference to embodiments thereof, it will be understood that various changes in form and details may be made therein without departing from the spirit and scope of the following claims.

What is claimed is:

1. A bonding apparatus for bonding a second substrate to a first substrate, the bonding apparatus comprising:
a support unit configured to support the first substrate; and
a bonding unit above the support unit and configured to attach the second substrate;
wherein the bonding unit includes:
a tip member facing the support unit; and
a head member on the tip member;
wherein the tip member includes:
a first part having a first region and a second region surrounding the first region, wherein the bonding apparatus is configured to eject a gas from the first region and the bonding apparatus is configured to form a vacuum in the second region; and
a second part extending from the first part toward the head member; and
wherein an area of a transverse section of the first part is less than an area of a transverse section of the second part.

2. The bonding apparatus of claim 1, wherein:
the bonding apparatus is configured to eject the gas such that a portion of the second substrate corresponding to the first region is protruded toward the first substrate by the ejected gas, and the bonding apparatus is configured to form the vacuum such that another portion of the second substrate corresponding to the second region is attached to the second region by the vacuum; and
the bonding apparatus is configured to move the bonding unit toward the support unit such that the protruding portion of the second substrate comes into contact with the first substrate, and the second substrate is bonded to the first substrate.

3. The bonding apparatus of claim 1, wherein the bonding apparatus is configured to attach the tip member to the head member by the vacuum and is configured to detach the tip member from the head member by releasing the vacuum.

4. The bonding apparatus of claim 1, wherein the first part includes:
at least one positive pressure hole formed in the first region, wherein the bonding apparatus is configured to form a positive pressure by ejecting the gas through the at least one positive pressure hole;
a trench formed in the second region;
a plurality of negative pressure holes formed in the trench, wherein the bonding apparatus is configured to form the vacuum by sucking the gas through the plurality of negative pressure holes; and
a plurality of protrusions formed between the plurality of negative pressure holes.

5. The bonding apparatus of claim 4, wherein a depth of the trench is substantially equal to a height of each of the plurality of protrusions.

6. The bonding apparatus of claim 4, wherein a top end of each of the plurality of protrusions is coplanar with the first region.

7. The bonding apparatus of claim 4, wherein
the head member includes a first channel connected to the at least one positive pressure hole and a second channel connected to the plurality of negative pressure holes.

8. The bonding apparatus of claim 1, wherein the tip member includes a metal or ceramic.

9. A bonding apparatus for bonding a second substrate to a first substrate, the bonding apparatus comprising:
a support unit configured to support the first substrate; and
a bonding unit above the support unit and configured to attach the second substrate;
wherein the bonding unit includes:
a tip member facing the support unit; and
a head member on the tip member;
wherein the tip member is attachable to and detachable from the head member;
wherein the tip member includes a first region and a second region surrounding the first region, wherein the bonding apparatus is configured to generate a positive pressure toward the first substrate in the first region, and the bonding apparatus is configured to generate a negative pressure toward the head member in the second region;
wherein the bonding apparatus is configured to protrude a portion of the second substrate corresponding to the first region toward the first substrate using the positive pressure, and the bonding apparatus is configured to attach another portion of the second substrate corresponding to the second region to the second region using the negative pressure; and
the bonding apparatus is configured to move the bonding unit toward the support unit such that the protruding portion of the second substrate comes into contact with the first substrate, and the second substrate is bonded to the first substrate.

10. The bonding apparatus of claim 9, wherein the bonding apparatus is configured to attach the tip member to the head member by the negative pressure and is configured to detach the tip member from the head member by releasing the negative pressure.

11. The bonding apparatus of claim 9, wherein a magnitude of the negative pressure in the second region is greater than a magnitude of the positive pressure in the second region.

12. The bonding apparatus of claim 9, wherein the tip member includes:
at least one positive pressure hole formed in the first region, wherein the bonding apparatus is configured to form the positive pressure in the at least one positive pressure hole;
a trench formed in the second region;
a plurality of negative pressure holes formed in the trench, wherein the bonding apparatus is configured to form the negative pressure in the plurality of negative pressure holes; and
a plurality of protrusions formed between the plurality of negative pressure holes.

13. The bonding apparatus of claim 12, wherein a depth of the trench is substantially equal to a height of each of the plurality of protrusions.

14. The bonding apparatus of claim 12, wherein a top end of each of the plurality of protrusions is coplanar with the first region.

15. The bonding apparatus of claim 12, wherein
the head member includes a first channel connected to the at least one positive pressure hole, a second channel connected to the plurality of negative pressure holes, and a third channel providing a negative pressure for attachment and detachment of the tip member.

16. The bonding apparatus of claim 9, wherein the tip member includes a metal or ceramic.

17. A bonding apparatus for bonding a second substrate to a first substrate, the bonding apparatus comprising:
a support unit configured to support the first substrate;
a bonding unit above the support unit and configured to attach the second substrate;
an alignment unit configured to measure a position of the first substrate and a position of the second substrate; and
a pressure unit configured to provide a gas and a vacuum to the bonding unit;
wherein the bonding unit includes:
a tip member including a first part and a second part extending from the first part, the second part having a larger transverse section than the first part, the first part including a first region and a second region surrounding the first region, wherein the bonding apparatus is configured to eject the gas from the first region and to form a positive pressure toward the first substrate, the bonding apparatus is configured to form a negative pressure in the second region by the vacuum, and the first region and the second region face the support unit; and
a head member to which the tip member is removably attached;
wherein the bonding apparatus is configured to protrude a portion of the second substrate corresponding to the first region toward the first substrate using the positive pressure, and the bonding apparatus is configured to attach another portion of the second substrate corresponding to the second region to the second region using the negative pressure; and
wherein the bonding apparatus is configured to move the bonding unit toward the support unit such that the protruding portion of the second substrate comes into contact with the first substrate, and the second substrate is bonded to the first substrate.

18. The bonding apparatus of claim 17, wherein the first part includes:
at least one positive pressure hole formed in the first region, wherein the bonding apparatus is configured to form the positive pressure in the at least one positive pressure hole;
a trench formed in the second region;
a plurality of negative pressure holes formed in the trench, wherein the bonding apparatus is configured to form the negative pressure in the plurality of negative pressure holes; and
a plurality of protrusions formed between the plurality of negative pressure holes;
wherein a depth of the trench is substantially equal to a height of each of the plurality of protrusions.

19. The bonding apparatus of claim 18, wherein:
the head member includes a first channel connected to the at least one positive pressure hole and a second channel connected to the plurality of negative pressure holes; and
the pressure unit includes a gas supply source configured to supply the gas through the first channel and a vacuum pump configured to provide the vacuum through the second channel.

20. The bonding apparatus of claim 18, wherein the alignment unit includes:
a photographing member configured to capture an image of an alignment mark of the first substrate and an image of an alignment mark of the second substrate;
an alignment determiner configured to analyze the images captured by the photographing member and determine an alignment state of the first substrate and the second substrate; and
an alignment controller configured to align the first substrate with the second substrate by controlling a movement of one of the bonding unit and the support unit.
